(19) United States
(12) Patent Application Publication
(10) Pub. No.: US 2007/0296007 A1
(43) Pub. Date: Dec. 27, 2007

(54) Shared ground contact isolation structure for high-density magneto-resistive RAM

(76) Inventors: Human Park, Paris (FR); Ulrich Klostermann, Fontainebleau (FR)

Correspondence Address: SLATER & MATSIL LLP, 17950 PRESTON ROAD, SUITE 1000, DALLAS, TX, 75252, US

(21) Appl. No.: 11/369,195

(22) Filed: Mar. 6, 2006

(30) Foreign Application Priority Data
Sep. 29, 2005 (DE) 10 2005 046 774.1

(51) Int. Cl. H01L 29/772; G11C 11/00

(52) U.S. Cl. 257/295; 365/158; 438/3; 257/E29.242; 257/E43.004

(57) ABSTRACT

A buried ground contact that connects the ground electrodes of transistors in adjacent memory cells that are separated by an isolation region is described. In some embodiments, the buried ground contact passes beneath the isolation region that separates cells to electrically connect the drain regions of transistors in adjacent cells. The buried ground may be connected to a metal ground line through via connections at intervals, outside of the active cell area. Use of this buried ground contact eliminates the need for individual ground connections to each cell, leading to a substantial reduction in cell size, and a consequent increase in cell density. The buried ground contacts of the invention can be used with a variety of devices, including MRAM and PCRAM devices.

This application claims priority to German Patent Application 10 2005 046 774.1, which was filed Sep. 29, 2005, and is incorporated herein by reference.

### TECHNICAL FIELD

The present invention relates generally to MAAM (Magneto-resistive Random Access Memory) devices, and more particularly to the design and manufacture of a shared ground contact isolation structure for use with an MRAM device or other semiconductor devices.

### BACKGROUND

One emerging technology for non-volatile memory is magneto-resistive random access memory (MRAM). A common form of MRAM is based on the tunnelling magneto-resistance (TMR) effect, in which each memory cell comprises a magnetic tunnel junction (MTJ). Such an MTJ may be formed from two ferromagnetic metal layers, with an insulating, or “barrier” layer placed between the metal layers. When a voltage is applied between the metal layers, a tunnel current flows. The tunnel resistance varies based on the relative directions of magnetization of the metal layers. The tunnel resistance is small when the directions of magnetization are parallel (typically representing a “0”), and large (approximately 10%-20% higher, at room temperature) when the directions of magnetization are anti-parallel (typically representing a “1”).

The metal layers in a typical MRAM MTJ include a “fixed” layer, in which the direction of the magnetization is fixed, and a “free” layer, in which the direction of the magnetization can be switched by application of currents. These currents are typically applied through conductive write lines referred to as bit lines and word lines, which are disposed so that the bit lines are orthogonal to the word lines. In an MRAM array, an MTJ memory cell is located at each intersection of a bit line with a word line.

In a typical MTJ cell, to switch the direction of magnetization of the free layer of a particular cell, currents are applied through the bit line and the word line that intersect at that cell. The direction of these currents determines the direction in which the magnetization of the free layer will be set. The combined magnitude of the currents through the word and bit lines must be sufficient to generate a magnetic field at their intersection that is strong enough to switch the direction of magnetization of the free layer.

One difficulty with such MRAM designs is that, because a magnetic field is used to write the cells, there is a risk of inadvertently switching memory cells that are adjacent to the targeted memory cell, due, for example, to inconsistencies in the magnetic material properties of the cells. Additionally, any memory cells located along the same word or bit line as the selected cell is subject to a portion of the magnetic switching field, and may be inadvertently switched. Other causes of undesired switching of cells may, for example, include fluctuations in the magnetic field, or alterations in the shape of the field.

In MRAM designs known as thermal select MRAMS, these difficulties are addressed by thermal heating. A heating current is applied to reduce the saturation magnetization for the selected cells. Using this method, only the heated cells can be switched, reducing the occurrence of inadvertent cell switching. In some designs, this heating may be achieved by passing a current through the barrier layer of a cell, the resistance of which heats the cell.

Another type of MRAM that addresses these difficulties uses current-induced spin transfer to switch the free layer of the MTJ. In such “spin-injection” MRAM, the free layer is not switched via application of a magnetic field generated by the bit lines and word lines. Instead, a write current is forced directly through the MTJ to switch the free layer. The direction of the write current through the MTJ determines whether the MTJ is switched into a “0” state or a “1” state. A select transistor connected in series with the MTJ may be used to select a particular cell for a write operation.

Another difficulty that is encountered in MRAM is the size of the cells. In the current highly competitive market for memory devices, it is necessary to achieve high density by minimization of cell size. Unfortunately, in many MRAM designs, it is very difficult to reduce the cell size to compete with other types of memory devices. This has several causes. First, MRAM cells generally require a drastically higher write current than conventional DRAM (Dynamic Random Access Memory), particularly when thermal select MRAM or spin injection MRAM is being used. Since the write current is limited by the transistor dimensions in a cell, the transistor dimensions may have to be relatively large in MRAM devices. Additionally, features such as the size of the individual ground contacts and via connections to a metal line for each memory cell are a large contributor to the size of cells in many NRAM designs.

Similar difficulties with cell size are encountered in other recent memory technologies, such as phase-change random access memories (PCRAM), in which data are written by using ohmic heating to change the phase of a material between an amorphous and a crystalline state. The heating operation in such PCRAM requires a relatively high write current, leading to difficulties similar to those encountered with MRAM.

What is needed in the art is a design for memory cells for use with high-write current memory technologies, such as MRAM, with reduced cell size.

### SUMMARY OF THE INVENTION

Embodiments of the present invention provide a way of reducing the cell size for cells in high-current devices, such as MRAM, by eliminating the need for an individual ground contact on each cell. This is done by using a buried ground contact that connects the ground electrodes of transistors in adjacent cells that are separated by an isolation region. In some embodiments, the buried ground contact passes beneath the isolation region that separates cells to electrically connect the drain regions of transistors in adjacent cells. To avoid problems due to increased resistance of this diffusion-based buried ground, in some embodiments, the buried ground may be connected to a metal ground line through a via connection at intervals, outside of any active cell area. Use of this buried ground contact eliminates the need for individual ground connections to each cell. Since the individual ground connections are typically formed using a via connection, they can require a large amount of space to allow for the possibility of slight misalignments. Thus, eliminating the need for these via contacts leads to a substantial reduction in cell size.

In some embodiments, additional reductions in cell size, and consequent increases in cell density, are achieved by using a cell design with two transistors per cell. This two-transistor design permits the sidewall spacers of the two gates of the transistors to be used to align a via connection from a magnetic tunnel junction or other device to the transistors, reducing the area required for this via connection. Additionally, the symmetry of this two-transistor design permits the isolation region between adjacent cells in the bit line direction to be eliminated, further increasing cell density.

In some embodiments, the buried ground contact is formed from heavily doped n+ regions that pass under the isolation region between cells in the word line direction. These n+ regions may be formed by implantation of an N-type dopant, such as arsenic or phosphorus, prior to filling the isolation region. Annealing is then used to activate the doped regions.

In accordance with embodiments of the invention, use of buried ground contacts and a two-transistor design to reduce cell size can be used with a variety of devices, including, without limitation, MRAM and PCRAM. Various types of MRAM devices, including thermal select MRAM devices and spin injection MRAM devices, can benefit from the higher cell densities that are achieved with the invention.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a perspective view of a prior art MRAM array;

FIGS. 2A and 2B show, respectively, a block diagram and a sample layout of a prior art thermal select MRAM cell;

FIGS. 3A and 3B show, respectively, a block diagram and a sample layout of a thermal select MRAM cell using buried ground contacts, in accordance with an embodiment of the present invention; and

FIGS. 4A and 4B show cross-sections illustrating buried ground contacts, in accordance with an embodiment of the invention.

### DETAILED DESCRIPTION OF ILLUSTRATIVE EMBODIMENTS

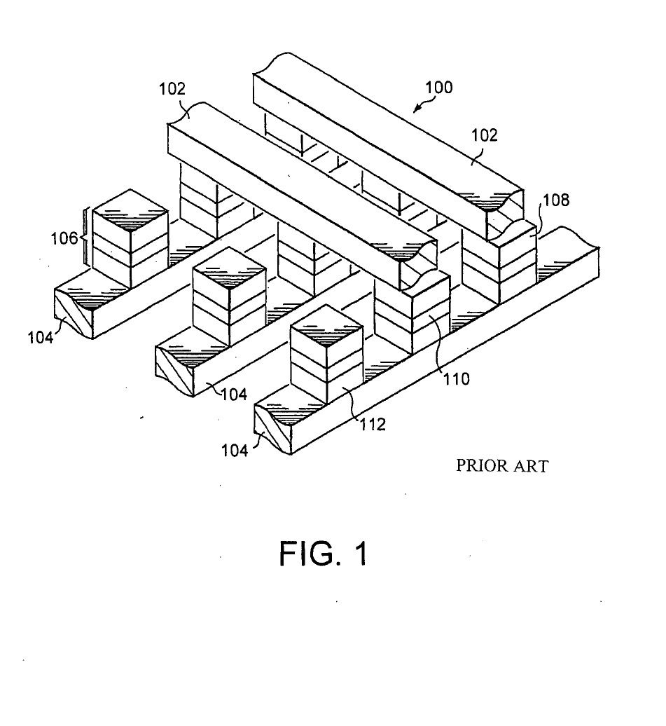

FIG. 1 shows a perspective view of a typical prior art MRAM array 100 having bit lines 102 disposed in an orthogonal direction to word lines 104 in adjacent metalization layers. Magnetic memory stacks 106 are electrically coupled to the bit lines 102 and word lines 104 (collectively, write lines), and are positioned between the bit lines 102 and word lines 104 at locations where a bit line 102 crosses a word line 104. The magnetic memory stacks 106 are preferably magnetic tunnel junctions (MTJs), comprising multiple layers, including a free layer 108, a tunnel layer 110, and a fixed layer 112. The free layer 108 and fixed layer 112 preferably comprise a plurality of magnetic metal layers (not shown). These magnetic metal layers may, for example, comprise eight to twelve layers of materials such as PtMn, CoFe, Ru, and NiFe. The tunnel layer 110 comprises a dielectric, such as Al₂O₃.

The fixed layer 112 is preferably magnetized in a fixed direction, while the direction of magnetization of the free layer 108 may be switched, changing the resistance of the magnetic memory stack 106. One bit of digital information may be stored in a magnetic memory stack 106 by running a current in the appropriate direction through the bit line 102 and the word line 104 that intersect at the magnetic memory stack 106, creating a sufficient magnetic field to set the direction of magnetization of the free layer 108. Information may be read from a magnetic memory stack 106 by applying a voltage across the magnetic memory stack, and measuring the resistance. If the direction of magnetization of the free layer 108 is parallel to the direction of magnetization of the fixed layer 112, then the measured resistance will be low, representing a value of “0” for the bit. If the direction of magnetization of the free layer 108 is anti-parallel to the direction of magnetization of the fixed layer 112, then the resistance will be high, representing a value of “1”.

It will be understood that the view shown in FIG. 1 is simplified, and that actual MRAM devices may include additional components. For example, in some MRAM designs, a transistor is coupled to each magnetic memory stack 106, for isolation. It will further be recognized that the view shown in FIG. 1 represents only a small portion of an actual MRAM device. Depending on the organization and memory capacity of the device, there may be hundreds or thousands of bit lines and word lines in a memory array. For example, a 1 Mb MRAM device (i.e., an MRAM device storing approximately one million bits of data) may include two arrays, each of which has 1024 word lines and 512 bit lines. Additionally, in some MRAM devices, there may be multiple layers of magnetic memory stacks, in which layers may share bit lines or word lines.

Variations in the MRAM technology in use may also lead to some variation in the basic design shown in FIG. 1. For example, in a typical thermal select MRAM, each cell includes a transistor (not shown) coupled between the MTJ and ground. The word line may be used to select the cell by being electrically connected to the gate of the transistor, so that a heating current flows through the cell from the bit line when the transistor is selected.

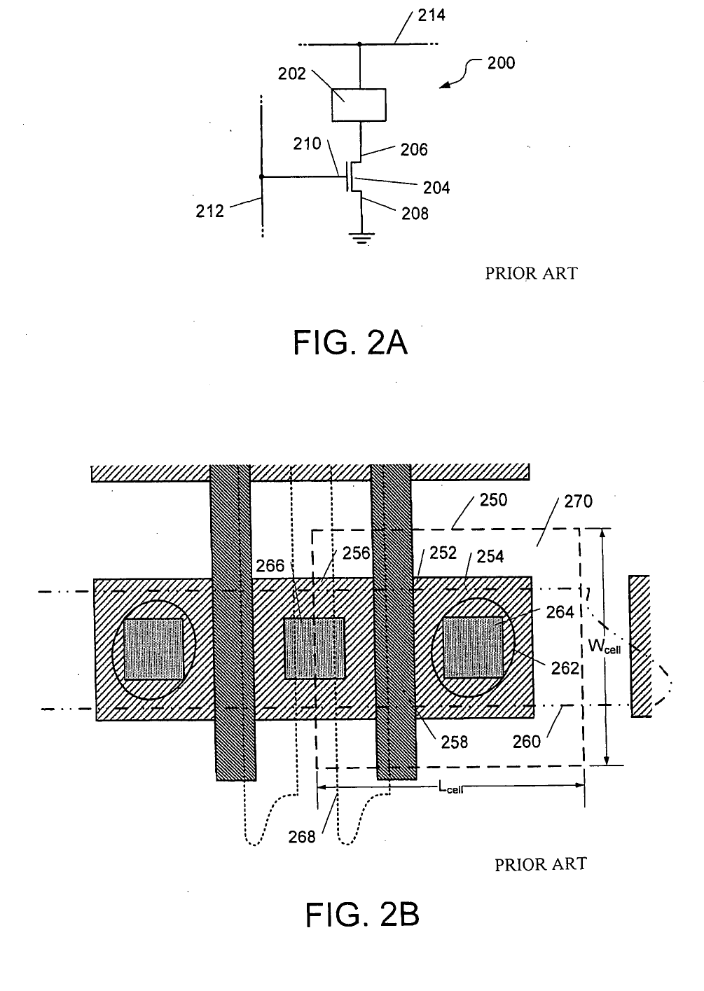

FIG. 2A shows a block diagram of a cell of a prior art thermal select MRAM device. A memory cell 200 includes a magnetic tunnel junction (MTJ) 202, electrically connected in series with a transistor 204. A source portion 206 of the transistor 204 is connected to the MTJ 202, a drain portion 208 of the transistor 204 is connected to ground, and a gate portion 210 of the transistor 204 is connected to a word line 212. A bit line 214 is electrically coupled to the MTJ 202. When the memory cell 200 is selected, a voltage on the word line 212 is applied to the gate portion 210 of the transistor 204, permitting current to flow from the bit line 214, through the MTJ 202 and the transistor 204. This current flow causes the heating of the MTJ 202, which permits a value to be written to the memory cell 200.

FIG. 2B shows an example layout for the prior art single transistor thermal select MRAM memory cell, such as is shown as a block diagram in FIG. 2A. For purposes of illustration, a 65 nm CMOS technology is used.

A memory cell 250 includes a transistor 252 having a source region 254, a drain region 256, and a gate 258. A bit line 260, in a metalization (M3) layer, is electrically connected to a magnetic tunnel junction (MTJ) 262, which is connected through a via connection 264 to the source region 254 of the transistor 252. The drain region 256 of the transistor 252 is electrically connected to a ground line (not shown) in a metalization (M1) layer (not shown) through a ground via connection 266. A word line 268 is electrically connected to the gate 258 of the transistor 252, so that a current may flow through the MTJ 262 and the transistor 252 when an activation voltage is applied on the word line 268. An isolation region 270 surrounds the transistor 252, electrically isolating the cell from other adjacent cells.

As can be seen in FIG. 2B, cell density is improved by sharing the drain region 256 and ground via connection 266 between the transistors of two adjacent cells. Thus, in measurements of the size of the memory cell 250, only half of the size of the drain region 256 and half of the size of the ground via connection 266 are included in the size of the cell 250.

In 65 nm CMOS technology, the overall width of the memory cell 250, W_{cell}, is approximately 300 nm. The length of the cell, L_{cell}, is approximately 325 nm. These sizes are determined by the minimum transistor width to handle the current necessary for writing to a thermal select MRAM cell, and by the size of the via contacts to the source region 254 and the drain region 256. In terms of the minimum feature size, F, of 65 nm, W_{cell} is 4.6 F, and L_{cell} is 5 F. This gives an overall cell area of 23 F².

To achieve a chip density that is competitive with other memory technologies, such as DRAM, it is necessary to reduce the size of the memory cell. For example, in 65 nm technology, an MRAM cell should be smaller than 10 F² to be competitive, where F is the minimum feature size (i.e., 65 nm). Therefore, it would be desirable to reduce the size of the cell by more than a factor of two.

In accordance with embodiments of the present invention, this is achieved by using a “buried” ground contact that connects the drain regions of the transistors of numerous cells. To avoid potential problems due to increased resistance of this diffusion-based buried ground, in preferred embodiments, the buried ground may be connected to a metal ground line through a via connection at intervals, outside of any active cell area.

Additionally, in some embodiments of a memory cell in accordance with the invention, each cell includes two transistors electrically connected in parallel, with a common source region. This arrangement increases the effective transistor width, thereby permitting higher write current. Additionally, the two transistors in parallel provide a way for a via contact to be formed in a self-aligned manner, using the gate poly sidewall spacers. This self-aligned contact permits a reduction in cell size, since it is not necessary to provide extra space to allow for slight misalignments.

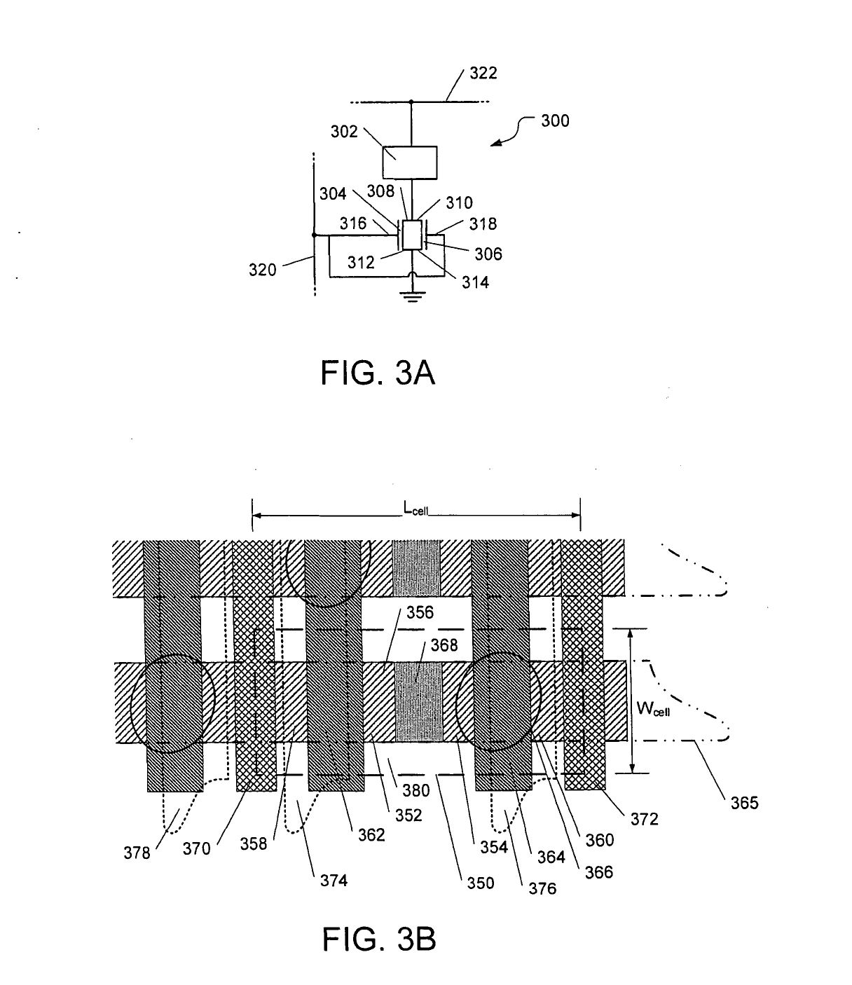

FIGS. 3A and 3B show an embodiment of a thermal select MRAM cell constructed in accordance with the principles of the present invention. In FIG. 3A, a block diagram of a memory cell 300 is shown. The memory cell 300 includes a magnetic tunnel junction (MTJ) 302, electrically coupled in series with transistors 304 and 306, which are coupled in parallel. Source portions 308 and 310 of transistors 304 and 306 are coupled to the MTJ 302, and drain portions 312 and 314 are coupled to ground. Gate portions 316 and 318 of the transistors 304 and 306 are coupled to a word line 320. A bit line 322 is electrically coupled to the MTJ 302. When the memory cell 300 is selected, a voltage on the word line 320 is applied to the gate portions 316 and 318 of the transistors 304, and 306 permitting current to flow from the bit line 322, through the MTJ 302 and the transistors 304 and 306. This current flow causes the heating of the MTJ 302, which permits a value to be written to the memory cell 300.

FIG. 3B shows an example layout for a thermal select MRAM memory cell in accordance with an embodiment of the present invention, such as is shown as a block diagram in FIG. 3A. As before, for purposes of illustration, a 65nm CMOS technology is used.

A memory cell 350 includes transistors 352 and 354, having a common source region 356, drain regions 358 and 360, and gates 362 and 364. A bit line 365, in a metalization layer, is electrically connected to a magnetic tunnel junction (MTJ) 366, which is coupled through a self-aligned via connection 368 to the common source region 356 of the transistors 352 and 354. It should be noted that although the MTJ 366 is not shown as being located directly above the self-aligned via connection 368, they are electrically connected in a layer that is not shown in FIG. 3B. Generally, the MTJs in an MRAM device may be placed in an offset position, such as is shown in FIG. 3B.

The drain region 358 of the transistor 352 is electrically connected to a buried ground contact 370, and the drain region 360 of the transistor 354 is electrically connected to a buried ground contact 372. In the embodiment shown in FIG. 3B, the buried ground contacts 370 and 372 are formed and shared between adjacent memory cells in the bit line direction, and couple the drain regions of numerous transistors in the word line direction. In accordance with the principles of the invention, these buried ground contacts replace the need for individual ground contacts and via connections on the drain regions of the transistors, permitting the cell size to be reduced.

On the drain regions 358 and 360, the ground contacts 370 and 372 are doped using known source/drain implantation, and silicided in self-alignment with the drain spacers of adjacent gates. The size of the contact area of the buried ground contacts 370 and 372 is defined by the width of the transistor, and the distance between sidewall spacers of adjacent gates. Generally, this area will be smaller than a typical ground contact designed according to the normal rules for the technology in which the memory device is fabricated.

A word line 374 is electrically connected to gates 362 and 364 of transistors 352 and 354, so that a current may flow through the MTJ 366 when an activation voltage is applied on the word line 374. A metal ground line 376, which, in this embodiment, runs in the same metalization layer as the word line 374, is connected with the buried ground contact 372 at intervals using via connections (not shown). These via connections are preferably formed in an area outside of the active area of a memory cell, so that they do not increase the size of the memory cells. Use of such a metal ground line can avoid potential problems due to increased resistance of diffusion-based ground contacts, such as buried ground contacts 370 and 372. A similar metal ground line 378 is connected with the buried ground contact 370. In some embodiments, the metal ground lines 376 and 378 may also be used as word lines.

An isolation region 380 isolates rows of cells from adjacent rows of cells in the word line direction. As will be illustrated below, the buried ground contacts 370 and 372 run beneath the isolation region 380, to connect the drain regions of the transistors of adjacent cells in the word line direction. The symmetric design of the cells, using two transistors per cell, permits the isolation regions between adjacent cells in the bit line direction to be eliminated, improving the memory cell density.

Use of the buried ground contacts eliminates the need to use individual via connections to the drain regions of each transistor. This permits the size of the transistors, and the cell size to be reduced. Additionally, in the embodiment shown in FIG. 3B, the cell size is further reduced by use of two transistors per cell. This permits the elimination of the isolation region between adjacent cells in the bit line direction, and use of a self-aligned via connection to the shared source region of the transistors in a cell, using the gate poly sidewall spacers for alignment of the via connection.

In 65 nm CMOS technology, the overall width of the memory cell 350, W_{cell}, is approximately 130 nm. The length of the cell, L_{cell}, is approximately 310 nm. In terms of the minimum feature size, F, of 65 nm, W_{cell} is approximately 2 F, and L_{cell} is approximately 4.8 F. This gives an overall cell area of 9.6 F². Since the size of the cell is less than 10 F , the density of the memory cells can be competitive with other memory technologies.

It will be understood by one skilled in the relevant arts that the layout shown in FIG. 3B is for illustrative purposes, and that the buried ground contact of the present invention may be used in other designs, and in other types of memory devices. For example, a similar design could be used to reduce the size of a spin-injection MRAM device or a PCRAM device.

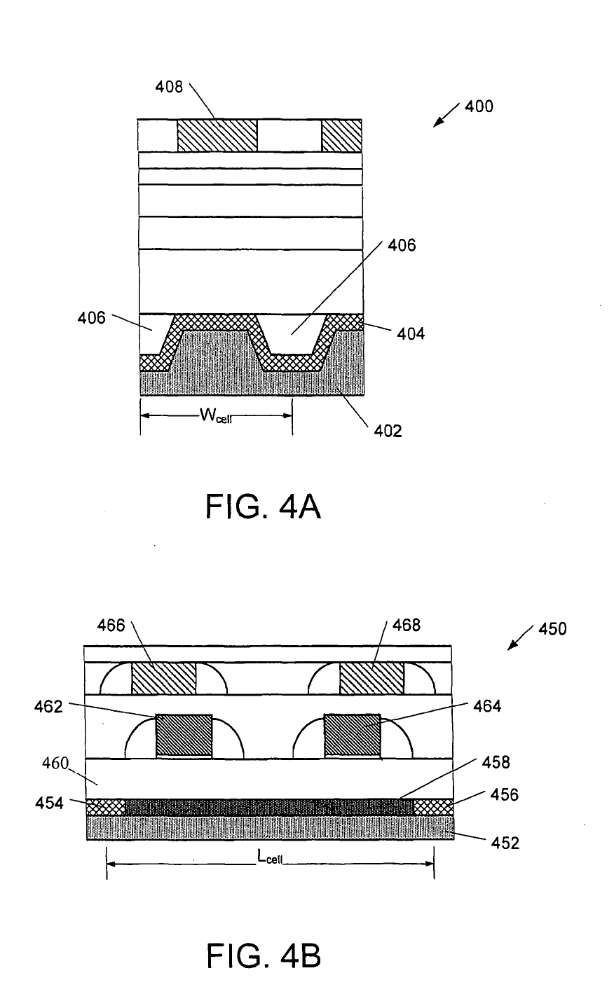

FIGS. 4A and 4B show cross sections of the memory cell shown in FIGS. 3A and 3B, in the word line and bit line directions. These cross sections show the doping design for the buried ground contacts. It should be noted that not all layers or connections are shown in FIGS. 4A and 4B, which are intended primarily to show the construction of the buried ground contacts.

In FIG. 4A, a cross-section 400 of a memory cell such as is shown in FIG. 3B, taken at an edge of the memory cell in the word line direction is shown. At the base of the cross-section 400 is a p-type substrate 402 for the transistors of the memory cell, which, in this embodiment, are NFETs. Alternatively, a p-well region may be substituted for the p-type substrate 402.

Next, heavily doped n+ regions 404 that pass under the shallow-trench isolation (STI) structures 406 that form the isolation region are used to form a buried ground contact. As discussed above, this buried ground contact links the ground electrodes of transistors in adjacent cells in the word line direction. The n+ regions 404 may be formed, for example, by implantation of an N-type dopant, such as arsenic or phosphorus, at an appropriate angle and rotation. This implantation typically occurs in the fabrication process after the STI trench is etched, and before the trench is filled with a dielectric material, such as silicon oxide. In a later process step, annealing activates the doped regions.

For purposes of orientation, a bit line 408 is shown in a metalization layer in the cross-section 400. The layers shown above the STI structure 406 are for illustration only, and there may be more or fewer such layers between the STI structure 406 and the metalization layer that includes the bit line 408.

FIG. 4B shows a cross-section 450 taken at an edge of a memory cell in the bit line direction. As before, at the base of the cross-section 450 is a p-type substrate 452, which may, alternatively, be replaced with a p-well region. Above the p-type substrate 452 are heavily doped n+ regions 454 and 456, which form buried ground contacts. The n+ regions 454 and 456 are separated by a heavily doped p+ region 458 underneath a shallow trench isolation (STI) structure 460. The p+ region 458 electrically isolates the ground contacts of the two transistors in a cell from each other. Additionally, the p+ region 458 may serve, in addition to the STI structure 460, to isolate adjacent memory cells in the word line direction. This is done by applying a negative bias to the p+ doped substrate, such as p+ region 458, while keeping a zero bias on n+ doped regions, such as n+ regions 454 and 456. The reverse-biased p-n junction provides junction isolation between adjacent transistors in the word line direction. Gates 462 and 464, as well as word line 466 and metal ground line 468 are also shown in FIG. 4B, for orientation.

The p+ region 458 may be formed by implantation of a p-type dopant, such a boron. Formation of the p+/n+ junction in the length direction can be achieved using a photolithographic mask during implantation. More than IF distance is kept between the two poly lines for the p+/n+ junction definition in the length direction.

While the invention has been shown and described with reference to specific embodiments, it should be understood by those skilled in the art that various changes in form and detail may be made therein without departing from the spirit and scope of the invention as defined by the appended claims. For example, in some designs, source and drain regions of transistors could be reversed, or n-type and p-type regions and/or substrates could be reversed. The scope of the invention is thus indicated by the appended claims and all changes that come within the meaning and range of equivalency of the claims are intended to be embraced.

What is claimed is:

1. A semiconductor device comprising:
a plurality of cells, each cell including a first transistor comprising a source region and a drain region;
an isolation region that separates a first cell in the plurality of cells from an adjacent cell in the plurality of cells; and
a buried ground contact that extends beneath the isolation region to electrically couple the drain region of the first transistor of the first cell to the drain region of the first transistor of the adjacent cell, the buried ground contact electrically coupled to a ground node.

2. The semiconductor device of claim 1, further comprising a metal ground line that is electrically coupled to the buried ground contact through a via connection, wherein the via connection is located outside of the area of a cell.

3. The semiconductor device of claim 1, wherein the buried ground contact comprises a heavily doped n+ region.

4. The semiconductor device of claim 1, wherein each cell includes a second transistor comprising a second drain region and a second buried ground contact that extends beneath the isolation region to electrically couple the drain region of the second transistor of the first cell to the drain region of the second transistor of the adjacent cell.

5. The semiconductor device of claim 4, wherein the first transistor and the second transistor have a common source region.

6. The semiconductor device of claim 5, wherein the first transistor and second transistor each comprise a gate having sidewall spacers.

7. The semiconductor device of claim 6, wherein the sidewall spacers of the gates of the first transistor and the second transistor provide alignment for a via connection to the common source region.

8. The semiconductor device of claim 1, wherein the semiconductor device comprises an MRAM device, and wherein each cell comprises a magnetic tunnel junction.

9. The semiconductor device of claim 8, wherein the magnetic tunnel junction is electrically coupled to the source region of the first transistor.

10. The semiconductor device of claim 8, wherein the MRAM device comprises a thermal select MRAM device.

11. The semiconductor device of claim 8, wherein the MRAM device comprises a spin injection MRAM device.

12. The semiconductor device of claim 1, wherein the semiconductor device comprises a PCRAM device.

13. A method of producing a semiconductor device, the method comprising:
forming a plurality of cells, each cell including a first transistor comprising a source region and a drain region;
forming an isolation region that separates a first cell in the plurality of cells from an adjacent cell in the plurality of cells; and
forming a buried ground contact that extends beneath the isolation region to electrically couple the drain region of the first transistor of the first cell to the drain region of the first transistor of the adjacent cell, the buried ground contact electrically coupled to ground.

14. The method of claim 13, further comprising electrically connecting the buried ground contact to a metal ground line through a via connection, wherein the via connection is formed outside of the area of a cell.

15. The method of claim 13, wherein forming the buried ground contact comprises implanting of an N-type dopant prior to forming the isolation region.

16. The method of claim 15, wherein forming the buried ground contact further comprises annealing following the implanting of the N-type dopant.

17. The method of claim 15, wherein forming the plurality of cells further comprises forming a second transistor in each cell, the second transistor comprising a second drain region, and
wherein the method further comprises forming a second buried ground contact that extends beneath the isolation region to electrically couple the drain region of the second transistor of the first cell to the drain region of the second transistor of the adjacent cell.

18. The method of claim 17, wherein forming the second transistor comprises forming the second transistor so that the first transistor and second transistor have a common source region.

19. The method of claim 18, wherein forming the plurality of cells further comprises forming a first gate having sidewall spacers for the first transistor and a second gate having sidewall spacers for the second transistor, and
wherein the method further comprises forming a via connection to the common source region using the sidewall spacers of the first transistor and the second gate to align the via connection.

20. The method of claim 13, wherein the semiconductor device comprises an MRAM device, and wherein forming the plurality of cells further comprises forming a magnetic tunnel junction for each cell in the plurality of cells.

21. A magneto-resistive random access memory device, comprising:
a plurality of memory cells, each memory cell in the plurality of memory cells comprising:
a first transistor comprising a first drain region and a first gate having sidewall spacers;
a second transistor comprising a second drain region and a second gate having sidewall spacers;
a common source region, shared by the first transistor and the second transistor;
a magnetic tunnel junction; and
a via connection, aligned by the sidewall spacers of the first transistor and the second transistor, the via connection electrically coupling the magnetic tunnel junction to the common source region,
an isolation region that separates a first memory cell in the plurality of memory cells from an adjacent memory cell in the plurality of memory cells;
a first buried ground contact that extends beneath the isolation region to electrically couple the drain region of the first transistor of the first memory cell to the drain region of the first transistor of the adjacent memory cell, the buried ground contact electrically coupled to ground; and
a second buried ground contact that extends beneath the isolation region to electrically couple the drain region of the second transistor of the first memory cell to the drain region of the second transistor of the adjacent memory cell, the buried ground contact electrically coupled to ground.

22. The magneto-resistive random access memory device of claim 21, further comprising:
a first metal ground line that is electrically coupled to the first buried ground contact through a first ground via connection, wherein the first ground via connection is located outside of the area of a cell; and
a second metal ground line that is electrically coupled to the second buried ground contact through a second ground via connection, wherein the second ground via connection is located outside of the area of a cell.
